(19) United States
(12) Patent Application Publication
(10) Pub. No.: US 2021/0340329 A1
(43) Pub. Date: Nov. 4, 2021

(54) CURABLE RESIN COMPOSITIONS WITH ENHANCED SHELF LIFE

(71) Applicant: Rohm and Haas Electronic Materials LLC, Marlborough, MA (US)

(72) Inventors: Michael MULZER, Grafton, OH (US); Sheng Liu, Bow, NH (US); Dung Quach, Marlborough, MA (US)

(21) Appl. No.: 17/195,706

(22) Filed: Mar. 9, 2021

Related U.S. Application Data
(60) Provisional application No. 63/017,255, filed on Apr. 29, 2020.

(51) Int. Cl. C08G 77/04; C09D 183/04; C09D 7/20; C09D 7/61; C09D 7/65; C09D 7/40; C09D 7/63

(52) U.S. Cl. CPC C08G 77/04; C09D 183/04; C09D 7/20; C09D 7/61; C09D 7/65; C08K 3/36; C09D 7/63; C08K 2201/006; C08K 2201/011; C08K 2201/005; C08K 2201/003; C09D 7/67

(57) ABSTRACT

Disclosed is a curable resin composition comprising: (a) a liquid siloxane oligomer comprising polymerized units of formula R¹ₘR²ₙSi(OR³)₄₋ₘ₋ₙ, wherein R¹ is a C₅-C₂₀ aliphatic group comprising an oxirane ring fused to an alicyclic ring, R² is a C₁-C₂₀ alkyl, C₆-C₃₀ aryl group, or a C₅-C₂₀ aliphatic group having one or more heteroatoms, R³ is a C₁-C₄ alkyl group or a C₁-C₄ acyl group, m is 0.1 to 2.0 and n is 0 to 2.0; (b) non-hollow nanoparticles of silica, a metal oxide, or a mixture thereof, the non-hollow nanoparticles having an average particle diameter from 5 to 50 nm; (c) a volatile monoprotic alcohol cosolvent; (d) a surfactant; and (e) a photoacid generator. Further disclosed are associated methods and manufactured articles.

### CLAIM OF BENEFIT OF PRIOR APPLICATION

This application claims the benefit of U.S. Provisional Application No. 63/017,255, filed Apr. 29, 2020, which is incorporated in its entirety herein by reference.

### BACKGROUND OF THE INVENTION

### 1. Field of the Disclosed and Claimed Inventive Concepts

The presently disclosed process(es), procedure(s), method(s), product(s), result(s), and/or concept(s) (collectively referred to hereinafter as the “present disclosure”) relate generally to compositions and coatings prepared therefrom. In particular, nanoparticle-based compositions with enhanced shelf-life and associated coatings are disclosed with properties that are well suited for electronics and displays applications.

### 2. Background and Applicable Aspects of the Presently Disclosed and Claimed Inventive Concept(s)

An optically clear hard polymeric coating can be useful in electronic and display devices. Conventional compositions for this purpose generally relied on either sol-gel chemistry or photo-curable cross-linked urethane acrylates. More recently, silanes and epoxy resins have been used to make hardcoatings for the target applications, e.g., U.S. Pat. No. 7,790,347. Nanoparticles can also be used to increase coating hardness. The specific polymeric coatings used in any electronic or display application are particular to the intended end use and requisite properties for the construction of a robust device. In flexible display applications, for example; the primary properties of interest include high optical transparency, high pencil hardness, and sufficient flexibility to enable flexible behavior. It can sometimes be true in these circumstances that maximum coating hardness is sacrificed in the name of flexibility. In end-uses where flexibility is less important, however, the construction of robust electronic and display devices is often better enabled by using coatings that maximize hardness.

Coatings formulations intended to deliver such high hardness generally trend towards the inclusion of increasing relative concentrations of silica and/or other metal oxide nanoparticles. Such high nanoparticle content can, however, lead to increased formulation de-stability which is manifest as formulation gelling over time under ambient storage conditions. This can place practical limitations on the development of high-hardness coating formulations intended for use in rigid electronics and displays applications. Formulations may require storage in low-temperature holding areas, or they might have to be used/coated very quickly onto the intended substrate(s) after the formula is generated. Neither of these solutions is ideal. There is thus an ongoing need for coating formulations with high hardness and increased shelf life.

### DETAILED DESCRIPTION

Before explaining at least one embodiment of the present disclosure in detail, it is to be understood that the present disclosure is not limited in its application to the details of construction and the arrangement of the components or steps or methodologies set forth in the following description. The present disclosure is capable of other embodiments or of being practiced or carried out in various ways. Also, it is to be understood that the phraseology and terminology employed herein is for the purpose of description and should not be regarded as limiting.

Unless otherwise defined herein, technical terms used in connection with the present disclosure shall have the meanings that are commonly understood by those of ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the present disclosure pertains. All patents, published patent applications, and non-patent publications referenced in any portion of this application are herein expressly incorporated by reference in their entirety to the same extent as if each individual patent or publication was specifically and individually indicated to be incorporated by reference.

All of the articles and/or methods disclosed herein can be made and executed without undue experimentation in light of the present disclosure. While the articles and methods of the present disclosure have been described in terms of preferred embodiments, it will be apparent to those of ordinary skill in the art that variations may be applied to the articles and/or methods and in the steps or in the sequence of steps of the method(s) described herein without departing from the concept, spirit and scope of the present disclosure. All such similar substitutes and modifications apparent to those skilled in the art are deemed to be within the spirit, scope and concept of the present disclosure.

As utilized in accordance with the present disclosure, the following terms, unless otherwise indicated, shall be understood to have the following meanings.

The use of the word “a” or “an” when used in conjunction with the term “comprising” may mean “one,” but it is also consistent with the meaning of “one or more,” “at least one,” and “one or more than one.” The use of the term “or” is used to mean “and/or” unless explicitly indicated to refer to alternatives only if the alternatives are mutually exclusive, although the disclosure supports a definition that refers to only alternatives and “and/or.” Throughout this application, the term “about” is used to indicate that a value includes the inherent variation of error for the quantifying device, the method(s) being employed to determine the value, or the variation that exists among the study subjects. For example, but not by way of limitation, when the term “about” is utilized, the designated value may vary by plus or minus twelve percent, or eleven percent, or ten percent, or nine percent, or eight percent, or seven percent, or six percent, or five percent, or four percent, or three percent, or two percent, or one percent. The use of the term “at least one” will be understood to include one as well as any quantity more than one, including but not limited to, 1, 2, 3, 4, 5, 10, 15, 20, 30, 40, 50, 100, etc. The term “at least one” may extend up to 100 or 1000 or more depending on the term to which it is attached. In addition, the quantities of 100/1000 are not to be considered limiting as lower or higher limits may also produce satisfactory results. In addition, the use of the term “at least one of X, Y, and Z” will be understood to include X alone, Y alone, and Z alone, as well as any combination of X, Y, and Z. The use of ordinal number terminology (i.e., “first”, “second”, “third”, “fourth”, etc.) is solely for the purpose of differentiating between two or more items and, unless otherwise stated, is not meant to imply any sequence or order or importance to one item over another or any order of addition.

As used herein, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. The terms “or combinations thereof” and “and/or combinations thereof” as used herein refer to all permutations and combinations of the listed items preceding the term. For example, “A, B, C, or combinations thereof” is intended to include at least one of: A, B, C, AB, AC, BC, or ABC and, if order is important in a particular context, also BA, CA, CB, CBA, BCA, ACB, BAC, or CAB. Continuing with this example, expressly included are combinations that contain repeats of one or more items or terms, such as BB, AAA, AAB, BBC, AAABCCCC, CBBAAA, CABABB, and so forth. The skilled artisan will understand that typically there is no limit on the number of items or terms in any combination, unless otherwise apparent from the context.

As used herein, the term “substantially” means that the subsequently described circumstance completely occurs or that the subsequently described circumstance occurs to a great extent or degree.

For purposes of the following detailed description, other than in any operating examples, or where otherwise indicated, numbers that express, for example, quantities of ingredients used in the specification and claims are to be understood as being modified in all instances by the term “about.” The numerical parameters set forth in the specification and attached claims are approximations that may vary depending upon the desired properties to be obtained in carrying out the invention.

The term “alicyclic” refers to a cyclic group that is not aromatic. The group can be saturated or unsaturated, but it does not exhibit aromatic character.

The term “alkyl” refers to a saturated linear or branched hydrocarbon group of 1 to 50 carbons. It further includes both substituted and unsubstituted hydrocarbon groups. The term is further intended to include heteroalkyl groups.

The term “aromatic compound” refers to an organic compound comprising at least one unsaturated cyclic group having 4n+2 delocalized pi electrons. The term is intended to encompass both aromatic compounds having only carbon and hydrogen atoms, and heteroaromatic compounds wherein one or more of the carbon atoms within the cyclic group has been replaced by another atom, such as nitrogen, oxygen, sulfur, or the like.

The term “aryl” or “aryl group” refers to a moiety formed by removal of one or more hydrogen (“H”) or deuterium (“D”) from an aromatic compound. The aryl group may be a single ring (monocyclic) or have multiple rings (bicyclic, or more) fused together or linked covalently. A “carbocyclic aryl” has only carbon atoms in the aromatic ring(s). A “heteroaryl” has one or more heteroatoms in at least one aromatic ring.

The term “alkoxy” refers to the group —OR, where R is alkyl.

The term “aryloxy” refers to the group —OR, where R is aryl.

Unless otherwise indicated, all groups can be substituted or unsubstituted. An optionally substituted group, such as, but not limited to, alkyl or aryl, may be substituted with one or more substituents which may be the same or different. Suitable substituents include alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)₂-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

The term “coating” refers to a covering that is applied to the surface of an object that is usually referred to as the “substrate.” Coatings may have various thicknesses and other properties, depending on the end-use appropriate for a given situation. In some non-limiting embodiments; the coating/substrate combination is used as a single unit, while in some embodiments, the coating is removed from the substrate for stand-alone use. In some non-limiting embodiments, the thus-removed coating is referred to as a film, a thin film, an optical thin film, or the like. A coating is considered optically transparent if it exhibits an average light transmittance of at least 80%, and preferably at least 85% over the wavelength range of 380-700 nm.

The term “hardcoat” refers to a coating exhibiting specific hardness properties as determined via any number of tests that are familiar to those skilled in the art. In some non-limiting embodiments, “pencil hardness” is one such measure. The measured hardness of a specific coating can make it more or less well-suited for specific applications that are generally known to those will skill in the arts in which the coating might find use.

The term “cosolvent” refers to substances added to a primary solvent intended to increase the solubility of poorly-soluble compounds. Alcohols may be used as cosolvents to dissolve hydrophobic molecules in a number of applications that are known to those with skill in the art. In some non-limiting embodiments, cosolvents are added to solvents in amounts such that they comprise from 0.05% to 30% by weight of the solvent component of a composition, mixture, or formulation.

The term “crosslinker” or “cross-linking reagent” refers to a molecule that contains two or more reactive ends capable of chemically attaching to specific functional groups on molecules or polymers. The crosslinked molecules or polymers are chemically joined together by one or more covalent bonds.

The term “curing” refers to a process during which a chemical reaction or physical action takes place; resulting in a harder, tougher, or more stable linkage or substance. In polymer chemistry, “curing” specifically refers to the toughening or hardening of a polymer via cross-linking of polymer chains. Curing processes may be brought about by electron beams, radiation, heat, and/or chemical additives.

The term “fused,” when applied to aromatic or alicyclic rings refers to an aromatic or alicyclic species that contains two or more joined rings that may share a single atom, two adjacent atoms, or 3 or more atoms.

The term “glass transition temperature (or T_{g})” refers to the temperature at which a reversible change occurs in an amorphous polymer or in amorphous regions of a semi-crystalline polymer where the material changes suddenly from a hard, glassy, or brittle state to one that is flexible or elastomeric. Microscopically, the glass transition occurs when normally-coiled, motionless polymer chains become free to rotate and can move past each other. T_{g}'s may be measured using differential scanning calorimetry (DSC), thermo-mechanical analysis (TMA), dynamic-mechanical analysis (DMA), or other methods.

The term “matrix” refers to a foundation on which one or more layers is deposited in the formation of, for example, an electronic device. Non-limiting examples include glass, silicon, and others.

The term “monomer” refers to a molecule that chemically bonds during polymerization to one or more monomers of the same or different kind to form a polymer.

The term “nonpolar” refers to a molecule, solvent, or other species in which the distribution of electrons between covalently-bonded atoms is even and there is thus no net electrical charge across them. In some embodiments; nonpolar molecules, solvents, or other species are formed when constituent atoms have the same or similar electronegativities.

The term “oligomer” refers to a molecule having from 3 to 200 polymerized monomer units, in some non-limiting embodiments at least 5, in some non-limiting embodiments at least 7; in some non-limiting embodiments no more than 175, in some non-limiting embodiments no more than 150.

The term “polar” refers to a molecule, solvent, or other species in which the distribution of electrons between covalently-bonded atoms is not even. Such species therefore exhibit a large dipole moment which may result from bonds between atoms characterized by significantly-different electronegativities.

The term “polyimide” refers to condensation polymers resulting from the reaction of one or more bifunctional carboxylic acid components with one or more primary diamines or diisocyanates. Polyimides contain the imide structure —CO—NR—CO— as a linear or heterocyclic unit along the main chain of the polymer backbone.

The term “polymer” refers to a large molecule comprising one or more types of monomer residues (repeating units) connected by covalent chemical bonds. By this definition, a polymer encompasses compounds wherein the number of monomer units may range from very few, which more commonly may be called as oligomers, to very many. Non-limiting examples of polymers include homopolymers and non-homopolymers such as copolymers, terpolymers, tetrapolymers and the higher analogues.

The term “protic” refers to a class of solvents that contain an acidic hydrogen atom and are therefore capable of acting as hydrogen donors. Common protic solvents include formic acid, n-butanol, isopropanol, ethanol, methanol, acetic acid, water, propylene glycol methyl ether (PGME), and others. Protic solvents can be used individually or in various combinations.

The term “monoprotic” refers to a class of protic solvents that contain a single acid hydrogen.

The term “satisfactory,” when regarding a materials property or characteristic, is intended to mean that the property or characteristic fulfills all requirements/demands for the material in-use.

The term “solubility” refers to the maximum amount of solute that can be dissolved in a solvent at a given temperature. In some embodiments, solubility may be measured or assessed by any number of qualitative or quantitative methods.

The term “substrate” refers to a base material that can be either rigid or flexible and may include one or more layers of one or more materials, which can include, but are not limited to, glass, polymer, metal or ceramic materials or combinations thereof. The substrate may or may not include electronic components, circuits, or conductive members.

As used herein, the term “flexible substrate” refers to a substrate capable of being bent or molded around a radius of ≤2 mm numerous times without breaking, permanent deformation, crease formation, fracture, crack formation, or the like. One suitable test for flexible substrates is whether the substrate can endure 100,000 or more bending cycles around a 2-mm radius at a frequency of 1 Hz. Exemplary flexible substrates include, but are not limited to, polyimide substrates, polyethylene-terephthalate substrates, polyethylene naphthalate substrates, polycarbonate substrates, poly(methyl methacrylate) substrates, polyethylene substrates, polypropylene substrates, and combinations thereof.

As used herein, the term “volatile” refers to a substance, often a liquid, that can be easily evaporated under what are considered standard conditions of temperature and pressure.

As used herein, the term “thermal acid generator” refers to a compound or compounds that, when heated, are capable of producing a strong acid or acids having a pKa of 2.0 or less. In one non-limiting embodiment, the thermal acid generator comprises a salt wherein a volatile base (e.g., pyridine) buffers a superacid (e.g., a sulfonate), and the mixture is heated above the heat of decomposition of the salt and the boiling point of the buffering base to remove the buffer and yield the strong acid. In another non-limiting embodiment, a thermal acid generator comprises a thermally-unstable buffer that breaks down upon heating to produce a strong acid. The use of thermal acid generators in electronics and displays applications described is described, for example, in U.S. 2014-0120469. A variety of thermal acid generators is commercially available.

In a structure where a substituent bond passes through one or more rings as shown below,

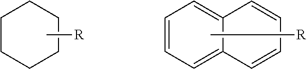

it is meant that the substituent R may be bonded at any available position on the one or more rings.

The phrase “adjacent to,” when used to refer to layers in a device, does not necessarily mean that one layer is immediately next to another layer. On the other hand, the phrase “adjacent R groups,” is used to refer to R groups that are next to each other in a chemical formula (i.e., R groups that are on atoms joined by a bond). Exemplary adjacent R groups are shown below:

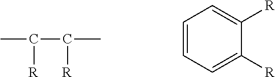

All percentages, ratios, and proportions used herein are based on weight unless otherwise specified. All operations are at room temperature (20-25° C.) unless otherwise specified. A material is considered to be a liquid if it is in the liquid state at room temperature. Average particle diameter is an arithmetic mean determined by Scanning Electron Microscopy and a Zetasizer Nano Z system. Surface area is determined using a BET surface area analyzer and reported as the arithmetic average. Number-average and weight-average molecular weights were determined against polystyrene standards. Samples were prepared by dilution with THF (HPLC grade, uninhibited, Fisher) to 0.5-1 wt %, then filtration (0.2 μm, PTFE). Injection volume: 100 μl; Eluent: THF; Columns: Sequence of four columns Shodex-KF805, Shodex-KF804, Shodex-KF803, Shodex-KF802; Flow rate: 1.2 mL/min; Column temperature: 35° C. A Waters 2414 refractive index detector was used.

The present disclosure is directed to a curable resin composition comprising: (a) a liquid siloxane oligomer comprising polymerized units of formula R¹ₘR²ₙSi(OR³)₄₋ₘ₋ₙ, wherein R¹ is a C₅-C₂₀ aliphatic group comprising an oxirane ring fused to an alicyclic ring, R² is a C₁-C₂₀ alkyl, C₆-C₃₀ aryl group, or a C₅-C₂₀ aliphatic group having one or more heteroatoms, R³ is a C₁-C₄ alkyl group or a C₁-C₄ acyl group, m is 0.1 to 2.0 and n is 0 to 2.0; (b) non-hollow nanoparticles of silica, a metal oxide, or a mixture thereof, the non-hollow nanoparticles having an average particle diameter from 5 to 50 nm; (c) a volatile monoprotic alcohol cosolvent; (d) a surfactant; and (e) a photoacid generator.

The present disclosure is further directed to a method for producing a polymeric coating, said method comprising: applying to a substrate a liquid curable resin composition comprising (a) a liquid siloxane oligomer comprising polymerized units of formula R¹ₘR²ₙSi(OR³)₄₋ₘ₋ₙ, wherein R¹ is a C₅-C₂₀ aliphatic group comprising an oxirane ring fused to an alicyclic ring, R² is a C₁-C₂₀ alkyl, C₆-C₃₀ aryl group, or a C₅-C₂₀ aliphatic group having one or more heteroatoms, R³ is a C₁-C₄ alkyl group or a C₁-C₄ acyl group, m is 0.1 to 2.0 and n is 0 to 2.0; (b) non-hollow nanoparticles of silica, a metal oxide, or a mixture thereof, the non-hollow nanoparticles having an average particle diameter from 5 to 50 nm; (c) a volatile monoprotic alcohol cosolvent; (d) a surfactant; and (e) a photoacid generator; soft baking the coated substrate; exposing the soft-baked coated substrate to UV radiation; performing a final thermal curing step.

The present disclosure is further directed to a hardcoat prepared using the disclosed compositions and methods; and manufactured articles that comprise the disclosed hardcoats.

In one non-limiting embodiment of the curable resin composition, the liquid siloxane oligomer comprising polymerized units of formula R¹ₘR²ₙSi(OR³)₄₋ₘ₋ₙ, R¹ contains at least 6 carbon atoms; in another non-limiting embodiment no more than 15, in another non-limiting embodiment no more than 12, in one non-limiting embodiment no more than 10. In one non-limiting embodiment, R¹ comprises an oxirane ring fused to an alicyclic ring having 5 or 6 carbon atoms, in another non-limiting embodiment 6, in another non-limiting embodiment a cyclohexane ring. In one non-limiting embodiment, R¹ contains no elements other than carbon, hydrogen and oxygen. In one non-limiting embodiment, R¹ is an epoxycyclohexyl group linked to silicon by a —(CH₂)ⱼ— group, where j is from 1 to 6, in one non-limiting embodiment one to four.

In one non-limiting embodiment of the liquid siloxane oligomer comprising polymerized units of formula R¹ₘR²ₙSi(OR³)₄₋ₘ₋ₙ, when R² is alkyl it contains no more than 15 carbon atoms, in another non-limiting embodiment no more than 12, in another non-limiting embodiment no more than 10. In one non-limiting embodiment, when R² is an aryl group it contains no more than 25 carbon atoms, in another non-limiting embodiment no more than 20, in another non-limiting embodiment no more than 16. In one non-limiting embodiment, the term “C₅-C₂₀ aliphatic group having one or more heteroatoms” refers to a C₅-C₂₀ aliphatic group having one or more of: a halogen such as fluorine; an ester group such as an acrylate group, a methacrylate group, a fumarate group, and a maleate group; a urethane group; and a vinyl ether group. In one non-limiting embodiment R² is a C₁-C₂₀ alkyl or C₆-C₃₀ aryl group, in another non-limiting embodiment C₁-C₂₀ alkyl. In an alternate non-limiting embodiment, R² is a C₁-C₂₀ alkyl or a C₅-C₂₀ aliphatic group having one or more heteroatoms, and in another non-limiting embodiment C₁-C₂₀ alkyl. In one non-limiting embodiment, when R³ is alkyl, it is methyl or ethyl, preferably methyl. When R³ is acyl, non-limiting embodiments include formyl and acetyl. One non-limiting example of a suitable resin is PC-2003 from Polyset Co. Inc. or those mentioned in U.S. Pat. No. 6,391,999.

In one non-limiting embodiment of the liquid siloxane oligomer comprising polymerized units of formula R¹ₘR²ₙSi(OR³)₄₋ₘ₋ₙ, m is at least 0.2; in another non-limiting embodiment at least 0.5; in another non-limiting embodiment no greater than 1.75, in another non-limiting embodiment no greater than 1.5; in another non-limiting embodiment no greater than 1.0; in another non-limiting embodiment no greater than 0.8.

In one non-limiting embodiment of the curable resin composition, the curable resin composition comprises at least 10/of the liquid siloxane oligomer; in another non-limiting embodiment at least 20%; in another non-limiting embodiment at least 21%; in another non-limiting embodiment at least 22%; in another non-limiting embodiment at least 23%; in another non-limiting embodiment at least 24%; in another non-limiting embodiment at least 25%; in another non-limiting embodiment at least 26%; in another non-limiting embodiment at least 27%; in another non-limiting embodiment at least 28%; in another non-limiting embodiment at least 29%; in another non-limiting embodiment at least 30%; in another non-limiting embodiment at least 31%. In one non-limiting embodiment of the curable resin composition, the curable resin composition comprises no more than 35% of the liquid siloxane oligomer; in one non-limiting embodiment no more than 34% of the liquid siloxane oligomer. In one non-limiting embodiment of the curable resin composition, the curable resin composition comprises no more than 55% of the liquid siloxane oligomer; in another non-limiting embodiment no more than 50%, in another non-limiting embodiment no more than 45%; in another non-limiting embodiment no more than 40%; in another non-limiting embodiment no more than 35%.

Any of the above embodiments of the liquid siloxane oligomers can be combined with one or more of the other embodiments, so long as they are not mutually exclusive. For example, the embodiment in which R¹ contains at least 6 carbon atoms can be combined with the embodiment in which R² is alkyl. The skilled person would understand which embodiments were mutually exclusive and would thus readily be able to determine the combinations of embodiments that are contemplated by the present application.

In one non-limiting embodiment of the curable resin composition, the non-hollow nanoparticles are silica; in another non-limiting embodiment zirconium oxide, or aluminum oxide; in another non-limiting embodiment a mixture of silica and zirconium oxide. In one non-limiting embodiment, the nanoparticles are approximately spherical in shape, but non-spherical shapes are possible, e.g. rod-shapes or ellipses. In one non-limiting embodiment the surface of the non-hollow nanoparticles is functionalized with substituent groups. These substituent groups can comprise functional groups (e.g., epoxy, acrylate, amino, vinyl ether, etc.) that can chemically react with functional groups contained in the silicon and non-silicon resins under a cationic photo curing process or thermal curing condition, but also comprise functional groups that are chemically inert under such conditions (e.g. alkyl, aryl, halogen etc.). In one non-limiting embodiment, a mixture of chemically reactive and chemically inert substituents is present on the surface of a given nanoparticle.

In one non-limiting embodiment of the curable resin composition, the non-hollow nanoparticles comprise a mixture of two or more different types of nanoparticles; in another non-limiting embodiment, the two or more different types of nanoparticles have diameters that differ from one another by 10% or less; in another non-liming embodiment; 5% or less; in another non-limiting embodiment, 1% or less. The two or more different types of nanoparticles in such compositions can be referred to by the term “having similar diameters.” In one non-limiting embodiment, the two or more different types of nanoparticles are functionalized with the same functional groups. In one non-limiting embodiment, the two or more different types of nanoparticles are functionalized with different functional groups.

In one non-limiting embodiment of the curable resin composition, the non-hollow nanoparticles have a surface area of at least 25 m²/g; in another non-limiting embodiment at least 50 m²/g; in another non-limiting embodiment at least 100 m²/g; in another non-limiting embodiment at least 200 m²/g; in another non-limiting embodiment at least 300 m²/g. In one non-limiting embodiment of the curable resin composition, the non-hollow nanoparticles have a surface area of less than 500 m²/g; in another non-limiting embodiment of less than 400 m²/g.

In one non-limiting embodiment, a mixture of nanoparticles can be used wherein the nanoparticles have similar average diameters in size but differ in the amount and chemical nature of substituents present on the surface of the particle. Additionally, the mixture can comprise nanoparticles which bear only substituents that are chemically inert under a cationic photo curing process or thermal curing condition, and nanoparticles that bear only substituents that are chemically reactive under a cationic photo curing process or thermal curing condition.

In one non-limiting embodiment, nanoparticles as useful in formulations disclosed herein are generally commercially available. They can be obtained in a variety of average particle diameters, surface treatments, and solvent systems. One non-limiting example is Admatechs, YA025C-MFK. A variety of other nanoparticles is available from this and other manufacturers.

In one non-limiting embodiment of the curable resin composition, the curable resin composition comprises at least 20% of the non-hollow nanoparticles; in another non-limiting embodiment at least 25%, in another non-limiting embodiment at least 30%; in another non-limiting embodiment 31%; in another non-limiting embodiment 32%; in another non-limiting embodiment 33%; in another non-limiting embodiment 34%; in another non-limiting embodiment 35%; in another non-limiting embodiment 36%; in another non-limiting embodiment 37%; in another non-limiting embodiment 38%; in another non-limiting embodiment 39%; in another non-limiting embodiment 40%; in another non-limiting embodiment 41%; in another non-limiting embodiment 42%; in another non-limiting embodiment 43%; in another non-limiting embodiment 44%; in another non-limiting embodiment 45%; in another non-limiting embodiment 46%; in another non-limiting embodiment 47%; in another non-limiting embodiment 48%; in another non-limiting embodiment 49%; in another non-limiting embodiment 50%.

In one non-limiting embodiment of the curable resin composition, the curable resin composition comprises no more than 70% of the non-hollow nanoparticles; in another non-limiting embodiment no more than 69%, in another non-limiting embodiment no more than 68%, in another non-limiting embodiment no more than 67%; in another non-limiting embodiment no more than 66%; in another non-limiting embodiment, no more than 65%.

It will be appreciated that a mixture of nanoparticles may be used in the present curable resin compositions. One example of a mixture of nanoparticles is a mixture of two or more different kinds of nanoparticles such as a mixture of silica and zirconium oxide nanoparticles. Such mixture of nanoparticles may be a mixture of two or more different nanoparticles having the same or similar average diameter, such as a mixture of 20-nm silica and 20-nm zirconium oxide or may be a mixture of two or more different nanoparticles having different average diameters, such as a mixture of 10-nm silica and 50-nm zirconium oxide. Another example of a mixture of nanoparticles is a mixture of two or more of the same nanoparticles but having different average diameters such as a mixture of first silica nanoparticles having an average diameter of 10-nm and second silica nanoparticles having an average diameter of 50-nm. When a mixture of silica and metal oxide nanoparticles are used in the present resin compositions, the total amount of the nanoparticles is from about 35 to 66 weight %.

Any of the above embodiments of the non-hollow nanoparticles can be combined with one or more of the other embodiments, so long as they are not mutually exclusive. For example, the embodiment in the nanoparticles are silica can be combined with the embodiment in which the nanoparticles are functionalized. The skilled person would understand which embodiments were mutually exclusive and would thus readily be able to determine the combinations of embodiments that are contemplated by the present application.

In one non-limiting embodiment of the curable resin composition, the resin composition further comprises a solvent. If a solvent is present, the amounts of the other components are calculated without including the solvent. In one non-limiting embodiment, the solvent is a C₃-C₁₀ organic solvent comprising oxygen, preferably a C₃-C₁₀ ketone, ester, ether or a solvent having more than one of these functional groups. In one non-limiting embodiment, the solvent is aliphatic. In one non-limiting embodiment, the solvent molecule contains no more than eight carbon atoms; in another non-limiting embodiment no more than seven carbon atoms; in another non-limiting embodiment no more than six carbon atoms. Preferably, the solvent molecule contains no atoms other than carbon, hydrogen and oxygen. Preferably, the solvent molecule contains no more than four oxygen atoms, preferably no more than three.

In some non-limiting embodiments; the solvent is selected from the group consisting of toluene, 2,4-dimethyl-3-pentanone, 1-butanol, propyleneglycol monomethylether, propylene-glycol monomethyletheracetate, methylisobutylketone, isoamyl acetate, acetone, methylethylketone, methylbutylketone, cyclohexanon, methylcellosolve, ethylcellosolve, cellosolveacetate, butylcellosolve, ethylether, dioxane, tetrahydrofuran, methyl acetate, ethyl acetate, propyl acetate, isopropyl acetate, butyl acetate, isobutyl acetate, pentyl acetate, 2-butanol, isobutylalcohol, isopropylalcohol, cyclohexanol, methylcyclohexanol, and xylene.

In one non-limiting embodiment of the curable resin composition, the resin composition comprises a volatile monoprotic alcohol cosolvent. Suitable cosolvents include 1-methoxypropan-2-ol (PGME); 1-ethoxypropan-2-ol (PGEE); 1-methoxy-2-methylpropan-2-ol; methyl lactate; ethyl lactate; methyl glycolate; hydroxyacetone; 1-methoxy-2-butanol; methyl 2-methoxyacetate; isopropanol; cyclopentanol; 2-methylbutan-1-ol; 4-methylpentan-2-ol; 3-methylbutan-2-ol.

In one non-limiting embodiment of the curable resin composition, the curable resin composition comprises 1% of the volatile monoprotic alcohol cosolvent; in another non-limiting embodiment 2%; in another non-limiting embodiment 3%; in another non-limiting embodiment 4%; in another non-limiting embodiment 5%; in another non-limiting embodiment 6%; in another non-limiting embodiment 7%; in another non-limiting embodiment 8%; in another non-limiting embodiment 9%; in another non-limiting embodiment 10%; in another non-limiting embodiment 11%; in another non-limiting embodiment 12%; in another non-limiting embodiment 13%; in another non-limiting embodiment 14%; in another non-limiting embodiment 15%; in another non-limiting embodiment more than 15%.

Any of the above embodiments of the solvents and cosolvents can be combined with one or more of the other embodiments, so long as they are not mutually exclusive. The skilled person would understand which embodiments were mutually exclusive and would thus readily be able to determine the combinations of embodiments that are contemplated by the present application.

In one non-limiting embodiment of the curable resin composition, the resin composition comprises a surfactant. In some non-limiting embodiments, the surfactant contains a majority of silicone units derived from the polymerization of the following monomers Si(R¹)(R²)(OR³)₂ wherein each R is independently chosen from a C₁-C₂₀ alkyl or a C₅-C₂₀ aliphatic group or a C₁-C₂₀ aryl group. In one non-limiting embodiment, the surfactant preferably is non-ionic and may contain at least two functional groups that can chemically react with functional groups contained in the silicon and non-silicon resins under a cationic photo curing process or thermal curing condition. A surfactant containing non-reactive groups is preferred in some non-limiting embodiments. In addition to silicon-derived units the surfactant may comprise units derived from the polymerization of an C₃-C₂M aliphatic molecule comprising an oxirane ring. In addition, the surfactant may comprise units derived from an C₁-C₅₀ aliphatic molecule comprising a hydroxyl group. In some non-limiting embodiments, the surfactant is free of halogen substituents. In some non-limiting embodiments, the molecular structure of the surfactant is predominantly linear, branched, or hyperbranched, or it may be a graft structure. In some non-limiting embodiments, the surfactant is selected from the group consisting of polyethers and perfluorinated polyethers.

A mixture of surfactants may be used wherein one or more of the surfactants are containing silicone-units and one or more surfactants are free of silicone-units. In some non-limiting embodiments, the surfactant free of silicone-units may comprise a majority of polyether groups or perfluorinated polyether groups.

The molecular weight of a suitable surfactant (as determined by GPC using tetrahydrofuran as an eluent and using polystyrene standards for calibration of the molecular weights as detected by refractive index measurements) is preferably above 1,000 Da and below 1,000,000 Da. In some non-limiting embodiments, the surfactant may have a mono-modal weight distribution or a multimodal weight distribution.

In one non-limiting embodiment, the surfactant is as described, for example, in Thin Solid Films 2015, vol. 597, p. 212-219. It is commercially available from BYK Additives and Instruments, and has structure:

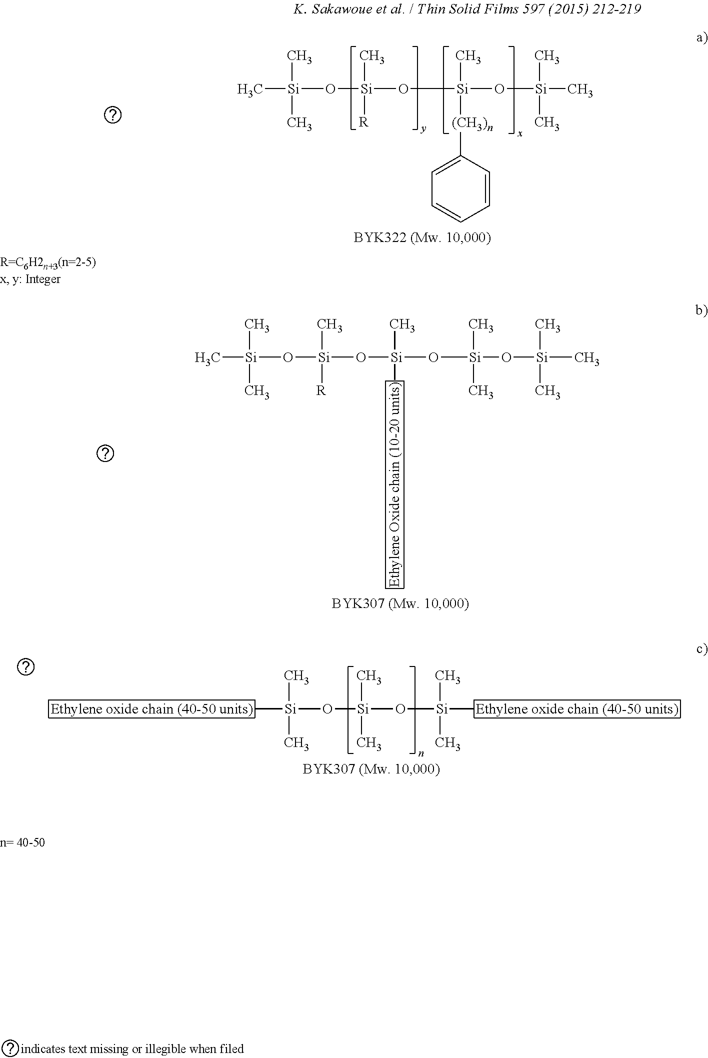

In some non-limiting embodiments, the surfactant is selected from the group consisting of, AD1700, MD700; Megaface F-1114, F-251, F-253, F-281, F-410, F-430, F-477, F-510, F-551, F-552, F-553, F-554, F-555, F-556, F-557, F-558, F-559, F-560, F-561, F-562, F-563, F-565, F-568, F-569, F-570, F-574, F-575, F-576, R-40, R-40-LM, R-41, R-94, RS-56, RS-72-K, RS-75, RS-76-E, RS-76-NS, RS-78, RS-90, DS-21 (DIC Sun Chemical); KY-164, KY-108, KY-1200, KY-1203 (Shin Etsu); Dowsil 14, Dowsil 11, Dowsil 54, Dowsil 57, Dowsil FZ2110, FZ-2123; Xiameter OFX-0077; ECOSURF EH-3, EH-6, EH-9, EH-14, SA-4, SA-7, SA-9, SA-15; Tergitol 15-S-3, 15-S-5, 15-S-7, 15-S-9, 15-S-12, 15-S-15, 15-S-20, 15-S-30, 15-S-40, L61, L-62, L-64, L-81, L-101, XD, XDLW, XH, XJ, TMN-3, TMN-6, TMN-10, TMN-100X, NP-4, NP-6, NP-7, NP-8, NP-9, NP-9.5, NP-10, NP-11, NP-12, NP-13, NP-15, NP-30, NP-40, NP-50, NP-70; Triton CF-10, CF-21, CF-32, CF76, CF87, DF-12, DF-16, DF-20GR-7M, BG-10, CG-50, CG-110, CG-425, CG-600, CG-650, CA, N-57, X-207, HW 1000, RW-20, RW-50, RW-150, X-15, X-35, X-45, X-114, X-100, X-102, X-165, X-305, X-405, X-705; PT250, PT700, PT3000, P425, P1000 TB, P1200, P2000, P4000, 15-200 (Dow Chemical); DC ADDITIVE 3, 7, 11, 14, 28, 2, 54, 56, 57, 62, 67, 71, 74, 76, 163 (DowCorning); TEGO Flow 425, Flow 370, Glide 100, Glide 410, Glide 415, Glide 435, Glide 432, Glide 440, Glide 450, Flow 425, Wet 270, Wet 500, Rad2010, Rad 2200 N, Rad 2011, Rad 2250, Rad 2500, Rad 2700, Dispers 670, Dispers 653, Dispers 656, Airex 962, Airex 990, Airex 936, Airex 910 (Evonik); BYK-300, BYK-301/302, BYK-306, BYK-307, BYK-310, BYK-315, BYK-313, BYK-320, BYK-322, BYK-323, BYK-325, BYK-330, BYK-331, BYK-333, BYK-337, BYK-341, BYK-342, BYK-344, BYK-345/346, BYK-347, BYK-348, BYK-349, BYK-370, BYK-375, BYK-377, BYK-378, BYK-UV3500, BYK-UV3510, BYK-UV3570, BYK-3550, BYK-SILCLEAN 3700, and BYK-SILCLEAN 3720 (BYK).

In one non-limiting embodiment of the curable resin composition, the curable resin composition comprises between 0.05 and 4.0 weight % surfactant; in another non-limiting embodiment between 0.1 and 2 weight %; in another non-limiting embodiment between 0.5 and 1 weight %.

Any of the above embodiments of the surfactants in the curable resin composition can be combined with one or more of the other embodiments, so long as they are not mutually exclusive. The skilled person would understand which embodiments were mutually exclusive and would thus readily be able to determine the combinations of embodiments that are contemplated by the present application.

In one non-limiting embodiment of the curable resin composition, the resin composition comprises a photoacid generator. The photoacid generator may comprise an anion wherein the negative charge is formally located on a boron, oxygen, nitrogen, carbon, antimony, gallium, aluminum, or phosphor atom. In one non-limiting embodiment the photoacid generator comprises an anion containing boron. In one non-limiting embodiment, the anion is B(R¹)(R²)(R³)(R⁴)⁻ wherein each R is independently chosen from a C₁-C₂₀ alkyl or a C₅-C₂₀ aliphatic group or a C₁-C₂₀ aryl group. Additional substituents may be present in each R, wherein the most preferred substituent is fluorine. In some non-limiting embodiments, the cation of the photoacid generator comprises a sulfur or iodine atom, more preferably iodine. In some non-limiting embodiments, the preferred structures are S(R¹)(R²)(R³)⁺ and I(R¹)(R²)⁺ wherein each R is independently chosen from a C₁-C₂₀ alkyl or a C₅-C₂₀ aliphatic group or a C₁-C₂₀ aryl group. Additional substituents may be present in each R. In some non-limiting embodiments, the photoacid generator is an ionic species comprising borate and sulfonium/iodonium species. In one non-limiting embodiment, the structure of the photoacid generator is

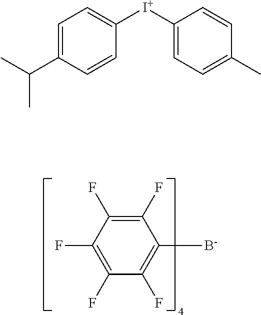

In some non-limiting embodiments, the photoacid generator is soluble in the same solvents as disclosed elsewhere herein. The photoacid generator is generally present in solution in an amount of 40 weight % solids or higher. Further, the photoacid generator preferably has a UV/visible absorption spectrum in which no major absorption peak is visible in a particular range of the absorption spectrum. Further, the photoacid generator preferably has a UV/visible absorption spectrum in which no major absorption peak is visible in the range of 350 nm or greater to 900 nm.

In some non-limiting embodiments; the photoacid generator is selected from the group consisting of 4-Isopropyl-4′-methyldiphenyliodonium tetrakis(pentafluorophenyl)borate (Speedcure 939, Lambson), CPI 200K (San-Apro), Irgacure 290, diphenyl(4-(pheny-lthio)phenyl)sulfonium hexafluoroantimonate, a mixture of diphenyl(4-(phenylthio)-phenyl)sulfonium hexafluoroantimonate and (thiobis(4,1-phenylene))bis(diphenylsulfonium) bis(hexafluoroantimonate), (4-t-Butylacetyloxyphenol)diphenylsulfonium perfluoro-butanesulfonate (CAS 857285-80-4), 4-Isopropyl-4′-methyldiphenyliodonium hexafluorophosphate, (4-((2-hydroxytetradecyl)oxy)phenylxphenyl)iodonium hexafluoroantimonate, (4-phenylthiophenyl)diphenylsulfonium triflate, and a mixture of diphenyl(4-(phenylthio)phenyl)sulfonium hexafluorophosphate and (thiobis(4,1-phenylene))bis(diphenylsulfonium) bis(hexafluorophosphate).

In one non-limiting embodiment of the curable resin composition, the curable resin composition comprises between 0.05 and 4 weight % photoacid generator; in another non-limiting embodiment between 0.05 and 2 weight %: in another non-limiting embodiment between 0.1 and 1 weight %. In another non-limiting embodiment of the curable resin composition, the curable resin composition comprises a mixture of two or more photoacid generators within these concentration ranges.

Any of the above embodiments of the photoacid generator in the curable resin composition can be combined with one or more of the other embodiments, so long as they are not mutually exclusive. The skilled person would understand which embodiments were mutually exclusive and would thus readily be able to determine the combinations of embodiments that are contemplated by the present application.

Optionally, the resin composition may further comprise one or more organic nanoparticles such as core-shell rubber (CSR) nanoparticles. The optional CSR nanoparticles comprise a rubber particle core and a shell layer, such CSR particles having an average diameter of from 50 to 250 nm. The shell layer of the CSR nanoparticles provides compatibility with the resin composition and has limited swellability to facilitate mixing and dispersion of the CSR nanoparticles in the resin composition. Suitable CSR nanoparticles are commercially available, such as those available under the following tradenames: Paraloid EXL 2650 A, EXL 2655, EXL2691 A, available from The Dow Chemical Company, or Kane Ace® MX series from Kaneka Corporation, such as MX 120, MX 125, MX 130, MX 136, MX 551, or METABLEN SX-006 available from Mitsubishi Rayon, or Genioperl P52 from Wacker Chemie AG. The CSR nanoparticles may be present in the curable composition in an amount ranging from 0 to 10 weight %, preferably in an amount of at least 0.1 weight %, preferably in an amount of up to 6 weight %, based on the total weight of the resin composition. In one non-limiting embodiment, the resin composition further comprises one or more CSR nanoparticles; in another non-limiting embodiment a mixture of silica with one or more CSR nanoparticles or a mixture of zirconium oxide with one or more CSR nanoparticles.

Optionally, other additives can be added to the composition such as anti-oxidants, anti-statics agents, optical brighteners, UV stabilizers, or UV absorbers.

Optionally, reactive modifiers are added to the resin composition to modify the formulation for performance properties improvement. Such reactive modifiers include, without limitation, flexibility modifiers, hardness modifiers, viscosity modifiers, optical property modifiers, and the like. In one non-limiting embodiment, the reactive modifiers are present in the resin composition in a total amount from 0 to 20 weight %; in another non-limiting embodiment at least 1 weight %, in another non-limiting embodiment at least 4 weight %, in another non-limiting embodiment at least 8 weight %; in another non-limiting embodiment no more than 17 weight %, in another non-limiting embodiment no more than 15 weight %. In one non-limiting embodiment, the reactive modifier comprises at least two epoxycyclohexane groups or at least two oxetane rings, preferably two epoxycyclohexane groups. Reactive modifiers useful in the disclosed formations are shown below, grouped according to the property usually improved by their use.

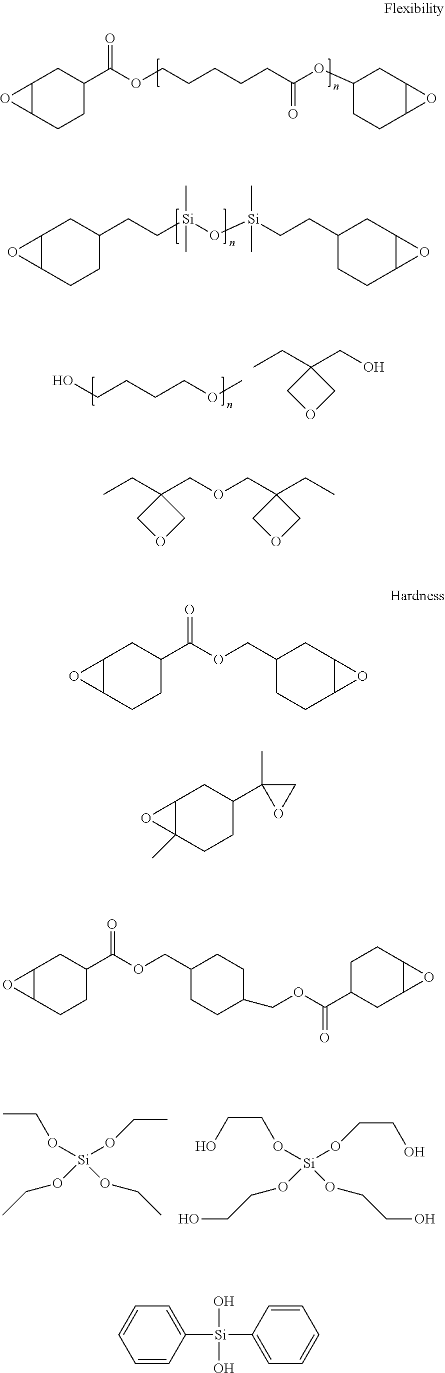

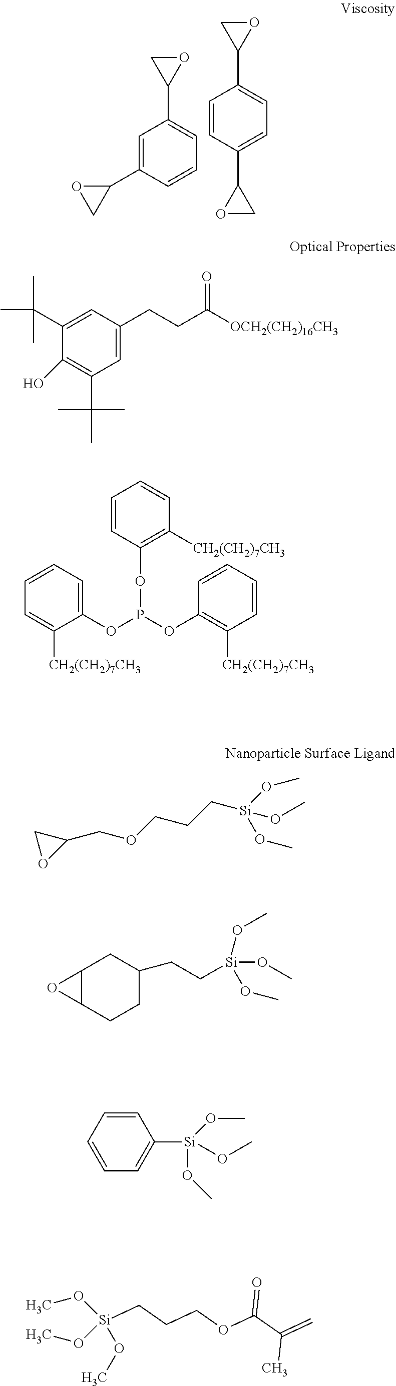

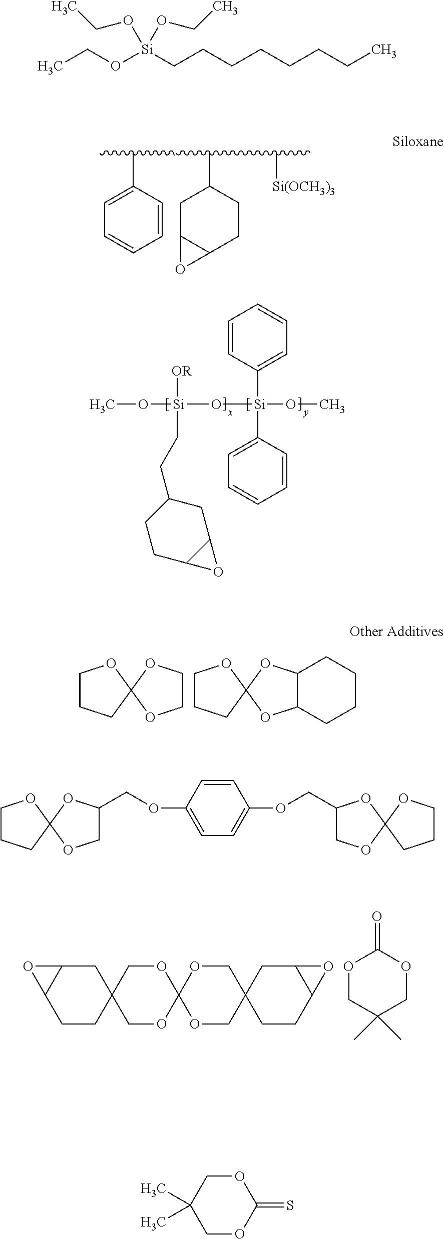

Additionally, a second epoxy-containing resin might be present comprising at least two C₅-C₂₀ aliphatic groups comprising an oxirane ring. Non-limiting examples include:

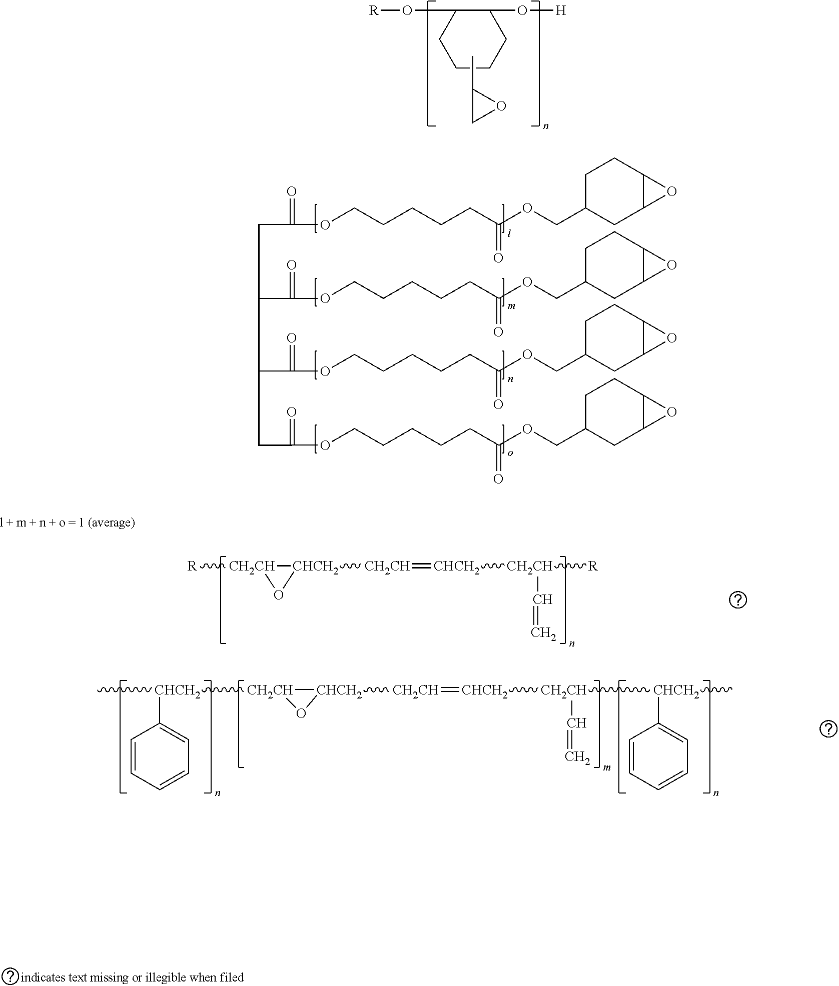

The curable resin compositions disclosed herein can exhibit increased stability-in-storage and shelf-life versus other formulations intended for similar end-uses. Shelf life is the maximum time interval that a compound or composition can be kept in a usable condition during storage. It can be dictated by the extent of continuing chemical reactions in the composition (crosslinking, etc) or phase separation (syneresis or settling). Hardcoat formulations often have high nanoparticle content in order to achieve the requisite hardness properties (pencil hardness, etc) demanded in the electronics and other industries. Such nanoparticle content can be inherently deleterious to shelf life of compositions intended to deliver the needed properties. An assessment of the relative components of shelf life can be measured relative to the various physical properties of the composition under applied, controlled deformations and forces. Dynamic viscosity is one such measurement. Curable resin compositions with enhanced shelf life retain lower dynamic viscosities as a function of time (measured in days) compared to lower-stability compositions.

The present disclosure is further directed to a method for producing a polymeric coating, said method comprising: applying to a substrate a liquid curable resin composition comprising (a) a liquid siloxane oligomer comprising polymerized units of formula R¹ₘR²ₙSi(OR³)₄₋ₘ₋ₙ, wherein R¹ is a C₅-C₂₀ aliphatic group comprising an oxirane ring fused to an alicyclic ring, R² is a C₁-C₂₀ alkyl, C₆-C₃₀ aryl group, or a C₅-C₂₀ aliphatic group having one or more heteroatoms, R³ is a C₁-C₄ alkyl group or a C₁-C₄ acyl group, m is 0.1 to 2.0 and n is 0 to 2.0; (b) non-hollow nanoparticles of silica, a metal oxide, or a mixture thereof, the non-hollow nanoparticles having an average particle diameter from 5 to 50 nm; (c) a volatile monoprotic alcohol cosolvent; (d) a surfactant; and (e) a photoacid generator; soft baking the coated substrate; exposing the soft-baked coated substrate to UV radiation; and performing a final thermal curing step.

Specific, non-limiting embodiments associated with the liquid curable resin composition in the method are identical to those disclosed herein for the liquid siloxane oligomer, the non-hollow nanoparticles, the alcohol cosolvent, the surfactant, and the photoacid generator in the context of the resin composition itself. In one non-limiting embodiment of the method for producing the polymeric coating, substrates are cleaned by filtered laboratory air. An automatic draw-down coater is used to cast the formulations on the substrate at room temperature. Draw-down bars with different gaps are used to obtain the desired coating thickness. The casted films are heated (soft-baked) to 90° C. on a hot-plate for three minutes in a fume hood, and then UV-cured using a Fusion 300 conveyor system (D bulb, irradiance −3000 mW/cm²). Each film passes the lamp two times at 47 feet per minute (fpm), respectively. The average values for energy density at 47 fpm are around 480, 120, 35, and 570 mJ/cm² in the UVA, UVB, UVC, and UVV regimes, respectively. Finally, the films are thermally cured for 10 minutes at 100° C. in a non-convection oven. All operations are carried out at a relative humidity level of 30-60% (at 20° C.). Persons with skill in the art would recognize the various parameter variations that are reasonable within this embodiment. Soft-baking, for example, may be performed at higher or lower temperatures and for greater or lesser periods of time. Similarly, the temperature and duration of the final thermal-cure step may be varied to accommodate specific materials' properties associated with the various compositions within the scope of this disclosure.

The present disclosure is further directed to a polymeric coating (hardcoat) prepared using the disclosed compositions and methods; and manufactured articles that include the disclosed polymeric coatings. The pencil hardness, and measurement thereof, have been discussed, for example, in U.S. 2017-0369654. In one non-limiting embodiment, the pencil hardness is measured at an applied force measured in units of kilogram-force (kgf)—a gravitational metric unit of force. It is equal to the magnitude of the force exerted on one kilogram of mass in a 9.80665 m/s² gravitational field (standard gravity, a conventional value approximating the average magnitude of gravity on Earth). Therefore, one kilogram-force is by definition equal to 9.80665 N. One kilogram-force is approximately 2.204622 pound-force. The polymeric coatings disclosed herein can be used as protective layers in a number of industrial and consumer products including, but not limited to, handheld/laptop computers, tablets, TVs, touch-displays, e-readers, smartphones, and electronic toys, and other commercial products.

The compositions, methods, and coatings, according to the present disclosure may be prepared and used as exemplified and set out below. The examples are presented herein for purposes of illustration of the present disclosure and are not intended to limit the scope of the invention described in the claims.

### EXAMPLES

### Resin Composition Preparation—Examples 1 and 2

The nanoparticle slurry was added to neat resin, and the mixture homogenized in a DAC 800.1 FVZ Speed Mixer (FlackTek Inc) at 1,800 rpm and 18° C. Additional solvent was added (in case of a solvent blend, the minor component was added first, then homogenized via vortex mixing, then the major solvent was added and the mixing routine repeated). Lastly, photoacid generator (“PAG”) solution and surfactant were added, and the final mixture homogenized using vortex mixing. The resulting formulation was then divided into several 20 mL scintillation vials, which then were capped and stored in an oven at 35° C. Table 1 reports the resin compositions associated with Examples 1 and 2. For shelf-life determinations, aliquots of the resin solutions were withdrawn at the indicated time intervals and their viscosities determined.

### Viscometer Measurement:

Dynamic viscosity data were acquired on an Anton Paar Stabinger Viscometer™ Model #SVM 3001 at ambient temperature. Reported values refer to the dynamic viscosity as measured in centipoise.

TABLE 1
Resin Compositions:

| Example | Resin Mw (wt %) | PAG (wt %) | NP slurry type (wt %) | Additional solvent (wt %) |
|---|---|---|---|---|
| 1 | 4.8 kDa (31) | 0.6 | YA025C-YJN (61) | 24DP (8) |
| 2 | 4.8 kDa (31) | 0.6 | YA025C-YJN (61) | 24DP/PGME (1:1 w/w) (8) |

Experimental compositions to investigate the impact of addition of protic solvents on shelf life of the hardcoat formulation. Weight percent values do not add up to 100% due to rounding. The study was conducted at 35° C. 24DP = 2,4-dimethyl-3-pentanone. The photoacid generator was triarylsulfonium hexafluoroantimonate salts, mixed (CAS 109037-75-4). The resin used was an epoxy-siloxane resin such as PC-2000 from Polyset.

TABLE 2
Viscosity Results:

| | Dynamic viscosity [cps] | | | | | |
|---|---|---|---|---|---|---|
| Example | Day 0 | Day 1 | Day 3 | Day 7 | Day 14 | Day 26 |
| 1 | 69 | 91 | — | 545 | gel | gel |
| 2 | 51 | 57 | 82 | 114 | 625 | gel |

Addition of the volatile monoprotic alcohol cosolvent is seen to increase the shelf-life in Example 2 as reflected in the delayed onset of formulation gelling.

TABLE 3
Resin Compositions:

| Example | Resin Mw (wt %) | PAG (wt %) | NP slurry type (wt %) | Solvent (wt %) | Additive (wt %) |
|---|---|---|---|---|---|
| 3 | 3.6 kDa (31) | PAG (1.2) | YA025C-YJN (61) | 24DP/PGME 9:1 (8) | — |
| 4 | 3.6 kDa (31) | PAG (1.2) | YA025C-YJN (61) | 24DP/PGME 9:1 (8) | BYK-307 (0.1) |
| 5 | 3.6 kDa (31) | PAG (1.2) | YA02SC-YJN (61) | 24DP/PGME 9:1 (8) | BYK-307 (0.25) |
| 6 | 3.6 kDa (31) | PAG (1.2) | YA025C-YJN (61) | 24DP/PGME 9:1 (8) | BYK-307 (0.5) |
| 7 | 3.6 kDa (31) | PAG (1.2) | YA025C-YJN (61) | 24DP/PGME 9:1 (8) | BYK-307 (1) |

Experimental compositions to investigate the impact of surfactant on shelf life of the hardcoat formulation. Weight percent values do not add up to 100% due to rounding. This study was conducted at 35° C. 24DP = 2,4-dimethyl-3-pentanone. The photoacid generator (PAG) was triarylsulfonium hexafluoroantimonate salts, mixed (CAS 109037-75-4). The resin used was an epoxy-siloxane resin such as PC-2000 from Polyset.

TABLE 4
Viscosity Results:

| | Dynamic viscosity [cps] | | | | |
|---|---|---|---|---|---|
| Example | Day 0 | Day 4 | Day 10 | Day 28 | Day 47 |
| 3 | 31 | 36 | 45 | 75 | gel |
| 4 | 30 | 33 | 40 | 46 | 134 |
| 5 | 29 | 32 | 34 | 42 | 69 |
| 6 | 30 | 32 | 35 | 41 | 55 |
| 7 | 33 | 36 | 38 | 41 | 51 |

The addition of even very small amounts of surfactant are seen to have a measurable effect on formulation shelf life as reflected in the dynamic viscosity measurements. Increasing concentrations of surfactant can lead to increased shelf life.

TABLE 5
Resin Compositions:

| Example | Resin Mw (wt %) | PAG type (wt %) | NP slurry type (wt %) | Solvent (wt %) | Additive (wt %) |
|---|---|---|---|---|---|
| 8 | 3.6 kDa (31) | PAG (1.2) | YA025C-YJN (61) | 24DP/PGME 9:1 (8) | BYK-307 (1) |
| 9 | 3.6 kDa (31) | CPI 200K (1.2) | YA025C-YJN (61) | 24DP/PGME 9:1 (8) | BYK-307 (1) |
| 10 | 3.6 kDa (31) | Irgacure 290 (1.2) | YA025C-YJN (61) | 24DP/PGME 9:1 (8) | BYK-307 (1) |

Experimental compositions to investigate the impact of PAG chemical nature on shelf life of the hardcoat formulation. Weight percent values do not add up to 100% due to rounding. This study was conducted at 35° C. For the photoacid generators: PAG has an antimony-based anion, CPI 200K has a phosphor-based anion, Irgacure 290 has a borate-based anion. The resin used was an epoxy-siloxane resin such as PC-2000 from Polyset.

TABLE 6
Viscosity Results:

| | Dynamic viscosity [cps] | | | | |
|---|---|---|---|---|---|
| Example | Day 0 | Day 7 | Day 23 | Day 35 | Day 43 |
| 8 | 26 | 36 | 62 | gel | gel |
| 9 | 26 | 37 | 58 | gel | gel |
| 10 | 21 | 25 | 29 | 36 | 55 |

The chemical composition of the photoacid generator is seen to have a measurable effect on formulation shelf life as reflected in the dynamic viscosity measurements.

Additional insights regarding the chemical nature of the photoacid generator and its impact on formulation shelf life can be ascertained via the following procedure. A formulation is prepared by first adding 2,4-dimethyl-3-pentanone (4.16 parts per weight) to an epoxy-siloxane resin (23.59 parts per weight, Polyset Co. Inc.) and vortex mixing until the resin is dissolved. A slurry of silica nanoparticles (71.16 parts per weight, 50 wt % solids, solvent mixture of 2,4-dimethyl-3-pentanone and propyleneglycolmonomethyl ether 9:1 w/w, Admatechs) is then added and vortex-mixed until homogenous. A solution of a photoacid generator (Table 7, 0.967 parts per weight, 50 wt % solids in either 2,4-dimethyl-3-pentanone or propylene carbonate as solvent) is then added, followed by a surfactant (0.120 parts per weight, BYK-307, BYK). The mixture is vortex-mixed until homogeneous. The formulation is then slowly rolled for 12 hours at 20° C. to ensure complete mixing. Subsequently, 7.5 g of the formulation is placed in a 20 mL scintillation vial which then is securely capped and placed in an oven at 35° C. The vial is then stored in the oven until the formulation had turned into a gel, i.e. there is no near-instantaneous flow of the formulation when the vial is turned upside down after equilibrating the vial to 20° C. The time required for the formulation to reach gelation while stored inside the oven is then noted and designated as the gelation time of the formulation.

TABLE 7
Photoacid Generators:

| | | | | Gel time |
|---|---|---|---|---|
| Example | Name | Cation type | Anion type | (days) |
| 11 | triphenylsulfonium | Sulfonium | perfluorosulfonate | 14 |
| | perfluorosulfonate | | | |
| 12 | (4- | Sulfonium | triflate | 15 |
| | phenylthiophenyl)diphenylsulfonium | | | |
| | trifiate | | | |
| 13 | Irgacure 250 | Iodonium | hexafluorophosphate | 28 |
| 14 | PC-2506 | Iodonium | antimonate | 28 |
| 15 | Triarylsulfonium | Sulfonium | hexafluorophosphate | 42 |
| | Hexafluorophosphate salts, mixed | | | |
| 16 | 4-Isopropyl-4′- | Iodonium | borate | 60 |
| | methyldiphenyliodonium | | | |
| | tetrakis(pentafluorophenyl)borate | | | |
| | (Speedcure 939) | | | |
| 17 | Irgacure 290 | Sulfonium | borate | 150 |

Additional insights regarding the chemical nature of the surfactant and its impact on formulation shelf life can be ascertained via the following procedure. A formulation is prepared by first adding 2,4-dimethyl-3-pentanone (4.16 parts per weight) to an epoxy-siloxane resin (23.59 parts per weight, Polyset Co. Inc.) and vortex mixing until the resin is dissolved. A slurry of silica nanoparticles (71.16 parts per weight, 50 wt % solids, solvent mixture of 2,4-dimethyl-3-pentanone and propyleneglycolmonomethyl ether 9:1 w/w, Admatechs) is then added and vortex mixed until homogenous. A solution of a photoacid generator (0.967 parts per weight, 50 w-6/o solids in 2,4-dimethyl-3-pentanone, 4-isopropyl-4′-methyldiphenyliodonium tetrakis(pentafluorophenyl)borate, Tokyo Chemical Industry) is then added, followed by a surfactant (Table 8, 0.120 parts per weight). The mixture is vortex mixed until homogeneous. The formulation is then slowly rolled for 12 hours at 20° C. to ensure complete mixing. Subsequently, 7.5 g of the formulation is placed in a 20 mL scintillation vial which then is securely capped and placed in an oven at 35° C. The vial is then stored in the oven until the formulation turns into a gel, i.e. there is no near-instantaneous flow of the formulation when the vial is turned upside down after equilibrating the vial to 20′° C. The time it takes for the formulation to reach gelation while stored inside the oven is then noted and designated as the gelation time of the formulation.

TABLE 8
Surfactants:

| | | | Gel time |
|---|---|---|---|
| Example | Surfactant name | Chemical description | (days) |
| 18 | BYK-313 | polyester-modified polydimethylsiloxane | 14 |
| 19 | BYK-307 | polyether-modified polydimethylsiloxane | 27 |
| 20 | BYK-342 | polyether-modified polydimethylsiloxane | 27 |
| 21 | DowCorning 54 | Siloxanes and Silicones, di-Me, Me | 29 |
| | | Hydrogen, reaction products with | |
| | | Polypropylene Glycol Monoallyl Ether | |
| 22 | AD1700 | perfluoropolyether | 29 |
| 23 | MD700 | perfluoropolyether | 29 |
| 24 | MegaFace 558 | perfluoropolyether | 30 |
| 25 | DowCorning 14 | silicone polyether | 37 |
| 26 | DowCorning 11 | silicone polyether | 43 |
| | DowCorning 57 | Dimethyl, | 43 |
| | | Methyl(propyl(poly(EO))acetate) | |
| | | Siloxane | |
| 28 | MegaFace RS-90 | perfluoropolyether | 43 |
| 29 | Tergitol 15-S-7 | C12—14H25—29O[CH2CH2O]7H | 47 |
| 30 | Tergitol 15-5-9 | C12—14H25—29O[CH2CH2O]9H | 58 |
| 31 | Tergitol 15-S-20 | C12—14H25—29O[CH2CH2O]20H | 69 |

Additional insights regarding the chemical nature of the solvent and its impact on formulation shelf life can be ascertained via the following procedure. A formulation is prepared by first adding 2,4-dimethyl-3-pentanone (4.16 parts per weight) to an epoxy-siloxane resin (23.59 parts per weight, Polyset Co. Inc.) and vortex mixing until the resin is dissolved. A slurry of silica nanoparticles (71.16 parts per weight, 50 wt % solids, solvent mixture of 2,4-dimethyl-3-pentanone and propyleneglycolmonomethyl ether 9:1 w/w, Admatechs) is then added and vortex mixed until homogenous. A solution of a photoacid generator (0.967 parts per weight, 50 wt % solids in 2,4-dimethyl-3-pentanone, 4-isopropyl-4′-methyldiphenyliodonium tetrakis(pentafluorophenyl)borate, Tokyo Chemical Industry) is then added, followed by a surfactant (0.120 parts per weight, BYK-307, BYK), followed by additional solvent (Table 9) to adjust the final solids content of the formulation to 55 wt % solids (The amount of additional co-solvent represents 18 wt % of total solvent content in the formulation). The mixture is vortex mixed until homogeneous. The formulation is then slowly rolled for 12 hours at 20° C. to ensure complete mixing. Subsequently, 7.5 g of the formulation is placed in a 20 mL scintillation vial which then is securely capped and placed in an oven at 35° C. The vial is then stored in the oven until the formulation turns into a gel, i.e. there is no near-instantaneous flow of the formulation when the vial is turned upside down after equilibrating the vial to 20° C. The time required for the formulation to reach gelation while stored inside the oven is then noted and designated as the gelation time of the formulation.

TABLE 9
Solvents:

| | | Gel time |
|---|---|---|
| Example | Name of co-solvent | (days) |
| 32 | cyclohexanone | 15 |
| 33 | 2,4-dimethyl-3-pentanone | 31 |
| 34 | cyclopentanol | 37 |
| 35 | cyclohexane | 41 |
| 36 | Propyleneglycol monomethyletheracetate | 45 |
| 37 | methylisobutylketone | 49 |
| 38 | isoamyl acetate | 50 |
| 39 | Hydroxyisobutyric acid methylester | 50 |
| 40 | toluene | 55 |
| 41 | Propyleneglycol monomethylether | 135 |

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification is to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A curable resin composition comprising:
(a) a liquid siloxane oligomer comprising polymerized units of formula R¹ₘR²ₙSi(OR³)₄₋ₘ₋ₙ, wherein R¹ is a C₅-C₂₀ aliphatic group comprising an oxirane ring fused to an alicyclic ring, R² is a C₁-C₂₀ alkyl, C₆-C₃₀ aryl group, or a C₅-C₂₀ aliphatic group having one or more heteroatoms, R³ is a C₁-C₄ alkyl group or a C₁-C₄ acyl group, m is 0.1 to 2.0 and n is 0 to 2.0;
(b) non-hollow nanoparticles of silica, a metal oxide, or a mixture thereof, the non-hollow nanoparticles having an average particle diameter from 5 to 50 nm;
(c) a volatile monoprotic alcohol cosolvent;
(d) a surfactant; and
(e) a photoacid generator.

2. The curable resin composition according to claim 1; wherein the non-hollow nanoparticles have a surface area from 50 to 500 m²/g.

3. The curable resin composition according to claim 1; wherein R¹ contains 6 to 15 carbon atoms.

4. The curable resin composition according to claim 3; wherein when R² is an alkyl that contains no more than 15 carbon atoms.

5. The curable resin composition according to claim 4; wherein R¹ comprises an oxirane ring fused to an alicyclic ring comprising 5 or 6 carbon atoms.

6. The curable resin composition according to claim 1; wherein m is from 0.8 to 1.5.

7. The curable resin composition according to claim 6; wherein n is less than or equal to 0.5.

8. The curable resin composition according to claim 2; wherein the non-hollow nanoparticles have an average particle diameter from 10 to 40 nm.

9. The curable resin composition according to claim 8; wherein the non-hollow nanoparticles comprise a mixture of two different types of nanoparticles; wherein the two different types of nanoparticles have similar diameters and are functionalized with different functional groups.

10. The curable resin composition according to claim 1; wherein the liquid siloxane oligomer comprises 30 weight % to 40 weight % of the composition.

11. The curable resin composition according to claim 10; wherein the non-hollow nanoparticles comprise 47 weight % to 65 weight % of the composition.

12. The curable resin composition according to claim 11; wherein the volatile monoprotic alcohol cosolvent comprises 1 weight % to 15 weight % of the composition.

13. The curable resin composition according to claim 1; wherein the surfactant is selected from the group consisting of silicone surfactants, polyether surfactants, and combinations thereof.

14. The curable resin composition according to claim 13; wherein the surfactant comprises 0.05 weight % to 4.0 weight % of the composition.

15. The curable resin composition according to claim 1; wherein the photoacid generator is an ionic species comprising borate and sulfonium/iodonium species.

16. The curable resin composition according to claim 15; wherein the photoacid generator comprises 0.05 weight % to 2.0 weight % of the composition.

17. A method for producing a polymeric coating, said method comprising:
applying to a substrate a liquid curable resin composition comprising;
(a) a liquid siloxane oligomer comprising polymerized units of formula R¹ₘR¹ₙSi(OR³)₄₋ₘ₋ₙ, wherein R¹ is a C₅-C₂₀ aliphatic group comprising an oxirane ring fused to an alicyclic ring, R² is a C₁-C₂₀ alkyl, C₆-C₃₀ aryl group, or a C₅-C₂₀ aliphatic group having one or more heteroatoms, R³ is a C₁-C₄ alkyl group or a C₁-C₄ acyl group, m is 0.1 to 2.0 and n is 0 to 2.0;
(b) non-hollow nanoparticles of silica, a metal oxide, or a mixture thereof, the non-hollow nanoparticles having an average particle diameter from 5 to 50 nm;
(c) a volatile monoprotic alcohol cosolvent;
(d) a surfactant; and
(e) a photoacid generator;
soft baking the coated substrate;
exposing the soft-baked coated substrate to UV radiation;
performing a thermal curing step.

18. A hardcoat prepared according to the method of claim 17; wherein the hardcoat is characterized by a pencil hardness greater than or equal to 8H when measured at 1 kgf.

19. A manufactured article comprising the hardcoat according to claim 1; wherein the manufactured article is selected from the group consisting of electronic devices, optical devices, mobile phones, tablets, laptops, TVs, eReaders, watches, and touch-displays.
